(19) United States
(12) Patent Application Publication
(10) Pub. No.: US 2015/0357162 A1
(43) Pub. Date: Dec. 10, 2015

(54) JIG AND PLASMA ETCHING APPARATUS INCLUDING THE SAME

(71) Applicant: Samsung Electronics Co., Ltd., Suwon-si (KR)

(72) Inventors: Sang-Won Kim, Asan-si (KR); In-Sup Shin, Seoul (KR)

(21) Appl. No.: 14/730,460

(22) Filed: Jun. 4, 2015

(30) Foreign Application Priority Data
Jun. 5, 2014 (KR) 10-2014-0068067

(51) Int. Cl. H01J 37/32; H01L 21/687; H01L 21/67

(52) U.S. Cl. CPC H01J 37/32091; H01L 21/67069; H01L 21/68735

(57) ABSTRACT

A jig comprises a base constructed and arranged to be exposed to plasma for etching a native oxide layer on electronic devices. A pocket structure is on an upper surface of the base. The pocket structure includes pockets constructed and arranged to receive the electronic devices, The pocket structure has at least one passageway through which the plasma is moved in a horizontal direction between the pockets.

### RELATED APPLICATIONS

This application claims priority under 35 USC §119 to Korean Patent Application No, 10-2014-0068067, filed on Jun. 5, 2014 in the Korean Intellectual Property Office (KIPO), the content of which is herein incorporated by reference in its entirety.

### BACKGROUND

1. Field

Example embodiments relate to a jig and a plasma etching apparatus including the same. More particularly, example embodiments relate to a jig configured to receive semiconductor packages, and a plasma etching apparatus including the jig for etching a native oxide layer on semiconductor packages.

2. Description of the Related Art

Semiconductor fabrication processes are performed on semiconductor substrates to form a plurality of semiconductor chips. In order to mount each of the semiconductor chips on a printed circuit board (PCB), a packaging process may be performed on the semiconductor chip to form a semiconductor package.

During manufacture of the semiconductor package, a native oxide layer may be formed 2Q at a joint of the semiconductor package as a result of natural exposure to ambient atmosphere. The presence of a native oxide layer can cause an electrical disconnection to occur in the semiconductor package. A plasma treatment can be performed on the semiconductor package to remove the native oxide layer.

In such a plasma treatment process, semiconductor packages may be received in a jig, which is, in turn, loaded into a plasma etching apparatus. The jig may include a base and a pocket structure. The pocket structure may be arranged on the base in a cross shape to form a plurality of pockets. The pockets may be isolated from each other by the pocket structure.

Since the pockets may be isolated from each other, the plasma may be moved along vertical walls of the pocket structure. Accordingly, a vertical plasma sheath may be formed on the vertical walls of the pocket structure. As a result of this approach, the plasma may not be uniformly distributed among the pockets. Such non-uniform distribution can, in turn, negatively affect efficiency in removing the native oxide layer from the semiconductor packages.

### SUMMARY

Example embodiments provide a jig configured to uniformly distribute plasma in each of pockets provided therein.

Example embodiments also provide a plasma etching apparatus including the above-mentioned jig.

In an aspect, a jig comprises; a base constructed and arranged to be exposed to plasma for etching a native oxide layer on electronic devices; and a pocket structure on an upper surface of the base including pockets constructed and arranged to receive the electronic devices, the pocket structure having at least one passageway through which the plasma is moved in a horizontal direction between the pockets.

In some embodiments, the pocket structure comprises: first partition walls arranged on the upper surface of the base in a first direction; and second partition walls arranged on the upper surface of the base in a second direction, the second direction being substantially perpendicular to the first direction.

In some embodiments, the passageway is positioned at intersection locations of the first partition walls and the second partition walls.

In some embodiments, a line passing through the passageways corresponds to a diagonal line of the pockets.

In some embodiments, the passageway is positioned at the first partition walls.

In some embodiments, a line passing through the passageways is substantially parallel to the second direction.

In some embodiments, the passageway is positioned at a portion of the first partition walls corresponding to a central portion of the pockets.

In some embodiments, the passageway is positioned at the second partition walls.

In some embodiments, a line passing through the passageways is substantially parallel to the first direction.

In some embodiments, the passageway is positioned at a portion of the second partition walls corresponding to a central portion of the pockets.

In some embodiments, the passageway comprises: first passageways positioned at the first partition walls; and second passageways positioned at the second partition walls.

In some embodiments, a line connected between the first passageways is substantially parallel to the second direction, and a line connected between the second passageways is substantially parallel to the first direction.

In some embodiments, the base and the pocket structure comprise: a metal plate; and an insulating layer coated on the metal plate.

In an aspect, a plasma etching apparatus comprises: an etching chamber; a chuck on a bottom surface of the etching chamber; a nozzle configured to inject a reaction gas into the etching chamber; an antenna configured to generate plasma from the reaction gas over the chuck; and a jig including a base and a pocket structure, the base arranged on an upper surface of the chuck and constructed and arranged to receive semiconductor packages, and the pocket structure arranged on an upper surface of the base, the pocket structure including pockets constructed and arranged to receive the semiconductor packages, the pocket structure having at least one passageway through which the plasma is moved in a horizontal direction between the pockets.

In some embodiments, the antenna is positioned in the chuck.

In an aspect, a jig in a plasma processing apparatus, comprises: a base; first partition walls on the base, the first partition walls extending in a first horizontal direction, second partition walls on the base, the second partition walls extending in a second horizontal direction; pocket structures comprising neighboring first partition walls and neighboring second partition walls, the pocket structures constructed and arranged to receive electronic devices for plasma processing; and passageways in at least one of the first partition walls or second partition walls.

In some embodiments, the passageways are provided at corner regions of the pocket structures at intersection locations of the at least of the first partition walls or second partition walls.

In some embodiments, the passageways are provided at side regions of the pocket structures in the at least one of the first partition walls or second partition walls.

In some embodiments, the passageways are provided at corner regions of the pocket structures at intersection locations of the at least of the first partition walls and second partition walls, and at side regions of the pocket structures in the at least one of the first partition walls or second partition walls.

In some embodiments, the first and second partition walls have a first height relative to the base and wherein the passageways have a second height relative to the base, the first height being greater than the second height.

According to some example embodiments, there may be provided a plasma etching apparatus. The plasma etching apparatus may include an etching chamber, a lower electrode, a showerhead, an upper electrode and a jig. The lower electrode may be arranged on a bottom surface of the etching chamber. The showerhead may be configured to inject a reaction gas into the etching chamber. The upper electrode may be configured to generate plasma from the reaction gas together with the lower electrode. The jig may include a base and a pocket structure. The base may be arranged on an upper surface of the lower electrode. The pocket structure may be arranged on an upper surface of the base to form pockets configured to receive semiconductor packages. The pocket structure may have at least one passageway through which the plasma may be horizontally moved between the pockets.

According to example embodiments, the pocket structures may have the at least one passageway provided between neighboring pockets. Accordingly, plasma may be caused to flow in a horizontal direction between neighboring pockets through the passageway. As a result, the passageways provide a pathway to promote the flow of plasma so the plasma may be uniformly distributed among the pockets and so that the native oxide layer present on the semiconductor packages positioned in the pockets may be effectively and uniformly removed using the plasma

### BRIEF DESCRIPTION OF THE DRAWINGS

Example embodiments will be more clearly understood from the following detailed description taken in conjunction with the accompanying drawings. FIGS. 1 to 12 represent non-limiting, example embodiments as described herein.

FIG. 1 is a perspective view illustrating a jig in accordance with example embodiments in accordance with the inventive concepts;

FIG. 2 is an enlarged perspective view of a portion II of the embodiment of FIG. 1;

FIG. 3 is an enlarged plan view illustrating the jig of the embodiment of FIG. 1;

FIG. 4 is a cross-sectional view illustrating the jig of the embodiment of FIG. 1;

FIG. 5 is a perspective view illustrating a jig in accordance with example embodiments in accordance with the inventive concepts;

FIG. 6 is an enlarged perspective view of a portion VI of the embodiment of FIG. 5;

FIG. 7 is an enlarged plan view illustrating the jig of the embodiment of FIG. 5;

FIG. 8 is a perspective view illustrating a jig in accordance with example embodiments in accordance with the inventive concepts;

FIG. 9 is an enlarged perspective view of a portion IX of the embodiment of FIG. 8;

FIG. 10 is an enlarged plan view illustrating the jig of the embodiment of FIG. 8;

FIG. 11 is a cross-sectional view illustrating an inductively coupled plasma (ICP) etching apparatus including the jig of the embodiment of FIG. 1 in accordance with the inventive concepts; and

FIG. 12 is a cross-sectional view illustrating a capacitively coupled plasma (CCP) etching apparatus including the jig of the embodiment of FIG. 1 in accordance with the inventive concepts.

### DETAILED DESCRIPTION OF EMBODIMENTS

Various example embodiments will be described more fully hereinafter with reference to the accompanying drawings, in which some example embodiments are shown. The present inventive concepts may, however, be embodied in many different forms and should not be construed as limited to the example embodiments set forth herein. Rather, these example embodiments are provided so that this disclosure will be thorough and complete, and will fully convey the scope of the present inventive concepts to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concepts.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concepts.

Unless otherwise defined, all terms (including technical and scientific terms) used herein have the same meaning as commonly understood by one of ordinary skill in the art to which this specification belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

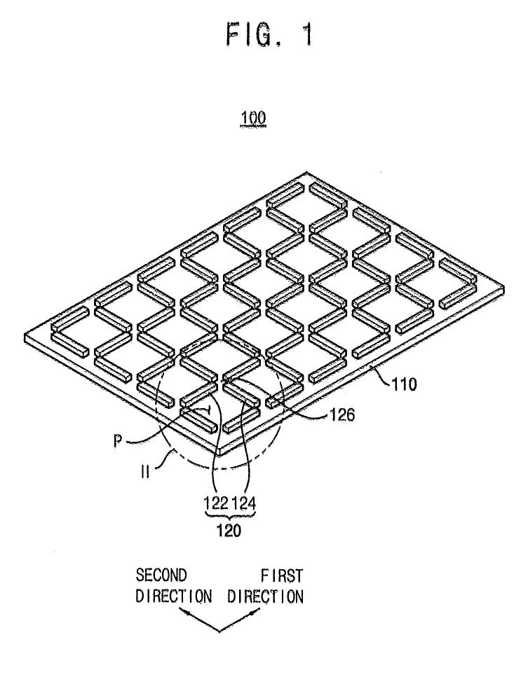

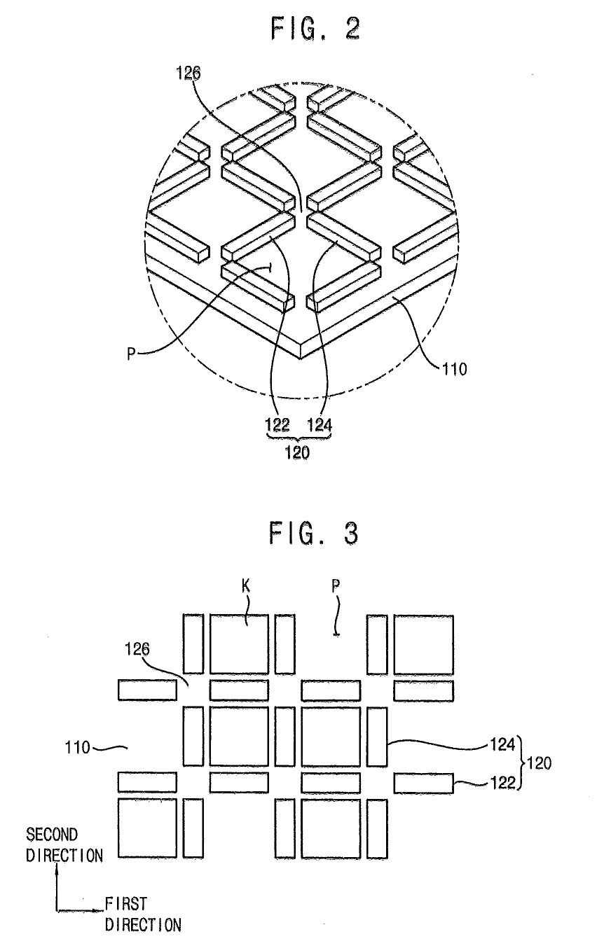

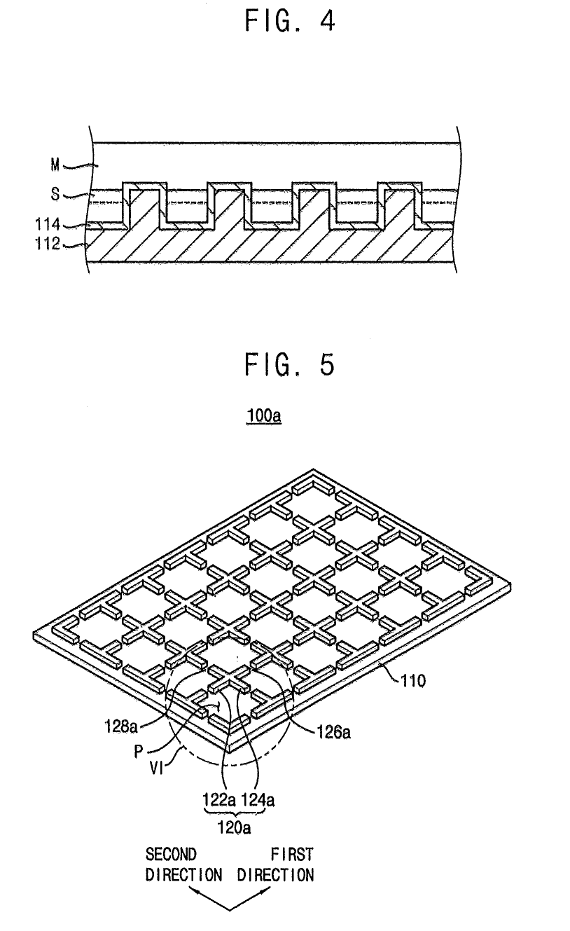

FIG. 1 is a perspective view illustrating a jig in accordance with example embodiments in accordance with the inventive concepts, FIG. 2 is an enlarged perspective view of a portion II in FIG. 1, FIG. 3 is an enlarged plan view illustrating the jig of the embodiment of FIG. 1, and FIG. 4 is a cross-sectional view illustrating the jig of the embodiment of FIG. 1.

Referring to FIGS. 1 to 3, a jig 100 of this example embodiment in accordance with the inventive concepts may be constructed and arranged to be employed in a process for removing a native oxide layer formed on electronic devices in a plasma treatment process. Accordingly, the jig 100 may comprise an element of a plasma etching apparatus. In some embodiments, the jig 100 may be arranged on a chuck of the plasma etching apparatus to receive electronic devices to be treated. In some embodiments, the electronic devices may include semiconductor packages K. In order to remove the native oxide layer formed, for example, at joint regions of the semiconductor package K, for example, at locations on which solder balls may be mounted, the semiconductor packages K received in the jig 100 may be exposed to the plasma. Therefore, in order to remove the native oxide layer on the semiconductor packages K at a uniform rate, it may be desired to uniformly distribute the plasma over the jig 100.

Referring to FIG. 4, the jig 100 may include a metal plate 112 and an insulating layer 114 coated on the metal plate 112. The insulating layer 114 may be exposed to the plasma. In some embodiments, the metal plate 112 may comprise aluminum, or other suitable base material. In some embodiments, the insulating layer 114 may comprise oxide, or other suitable insulating material. In some embodiments, the insulating layer 114 may include ceramic.

Referring to FIGS. 1 to 3, the jig 100 may include base 110 and one or more pocket structures 120. In some embodiments, the base 110 and the pocket structures 120 may comprise a double-layered structure including the metal plate 112 and the insulating layer 114.

In some embodiments, the base 110 may have a plate, or planar, shape. The base 110 may have a lower surface configured to communicate with the chuck, and an upper surface constructed and arranged to be exposed to the plasma treatment. In various embodiments, the base 110 may take the form of other shapes that are different from the planar, plate shape.

The pocket structures 120 may be arranged on the upper surface of the base 110 to form a plurality of pockets P configured, shaped, or otherwise constructed and arranged to receive semiconductor packages K. In some embodiments, the pocket structure 120 may include first partition walls 122 and second partition walls 124. In order to readily insert the semiconductor packages K into the pockets P, the first partition walls 122 and the second partition walls 124 may have a gradually decreased width from a lower end to an upper end of the first and second partition walls 122 and 124. In other words, the sidewalls of the first and second partition walls 122, 124 may be tapered.

In some embodiments, the first partition walls 122 may be arranged on the upper surface of the base 110 in a first direction so that the walls are parallel to each other in the first direction. For example, the first partition walls 122 may be arranged in rows that are spaced apart by a first interval.

In some embodiments, the second partition walls 124 may be arranged on the upper surface of the base 110 in a second direction so that the walls are parallel to each other in the second direction. In some embodiments, the second direction is substantially perpendicular to the first direction. For example, the second partition walls 124 may be arranged in rows that are spaced apart by a second interval. In some embodiments, the first interval may be substantially the same as the second interval. Thus, in this manner, the first partition walls 122 and the second partition walls 124 may intersect with each other in a cross shape to form pockets P that are square in shape.

As mentioned above, in order to uniformly remove the native oxide layer on the semiconductor packages K during a plasma treatment process, it may be required to uniformly distribute the plasma among the pockets P. In accordance with the present inventive concepts, the pocket structures 120 may have at least one passageway 126 through which the plasma may be transported in a horizontal direction between the pockets P.

In example embodiments, the passageways 126 may be formed at the points of intersection of the first partition walls 122 and the second partition walls 124. Because the passageways are at these points of intersection, in the present example embodiment, the first and second partition walls 122, 124 do not actually physical intersect. Rather, the passageways are located at the intersection of the longitudinal axes of the first and second partition walls 122, 124. Thus, regions connecting the pockets P may correspond to their corner regions, as shown. Therefore, the first partition walls 122 and the second partition walls 124 may include walls having a same length that may be discontinuously arranged in the first direction and the second direction. The plasma may be horizontally moved between the pockets P through the passageways 126.

Therefore, as shown in FIG. 4, a vertical plasma sheath S along the first partition walls 122 and the second partition walls 124 may be suppressed so that the plasma sheath S may be horizontally arranged substantially parallel to the upper surface of the base 110. As a result, the plasma M may be uniformly distributed in the pockets P so that the native oxide layer on the semiconductor packages K may be uniformly etched.

Alternatively, in some embodiments, reduced-height walls may be positioned at the passageways 126. In such as case, the walls present at the passageways 126 may have a second height that is less than first heights of the first and second partition walls 122 and 124. Since such passageways 126 may have a structure that still allowing the plasma to flow in a horizontal direction, the plasma may be transported among the pockets P via the passageways 126 having reduced-height walls. In some embodiments, the height of walls present at the passageways 126 is less than or equal to one-half the heights of the first and second partition walls 122 and 124.

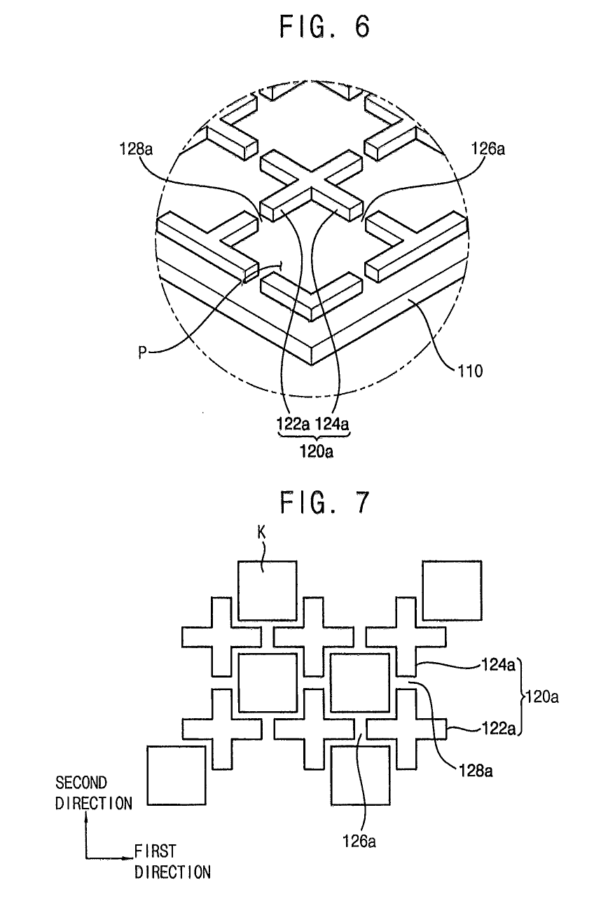

FIG. 5 is a perspective view illustrating a jig in accordance with example embodiments in accordance with the inventive concepts, FIG. 6 is an enlarged perspective view of a portion VI of the embodiment of FIG. 5, and FIG. 7 is an enlarged plan view illustrating the jig of the embodiment of FIG. 5, in accordance with the inventive concepts.

A jig 100a of this example embodiment may include elements that are substantially the same as those of the jig 100 in FIG. 1 except for configuration of the pocket structure. Thus, the same reference numerals may refer to the same elements and any further illustrations with respect to the same elements may be omitted herein for brevity.

Referring to FIGS. 5 to 7, a pocket structure 120a of this example embodiment may include first partition walls 122a and second partition walls 124a. The first partition walls 122a and the second partition walls 124a may have arrangements that are substantially the same as those of the first partition walls 122 and the second partition walls 124 in FIG. 1.

In the present embodiment, the first and second partition walls 124a, 124b physically intersect at the corner regions of the pockets P. First passageways 126a may be formed in the first partition walls 122a at a side portion of the pockets P. Second passageways 128a may be formed in the second partition walls 124a at a side portion of the pockets P. In some embodiments, the first and second passageways 126a, 126b can be formed a mid-portions of the first and second partition walls 122a, 122b. In other embodiments, the first and second passageways 126a, 126b can be formed at portions of the first and second partition walls 122a, 122b at positions other than their mid-portions. In some embodiments, a single passageway 126a, 126b can be formed in the portions of the first and second partition walls 122a, 122b between their intersection locations. In other embodiments, a more than one passageway 126a, 126b, for example two passageways 126a, 126b can be formed in the portions of the first and second partition walls 122a, 122b between their intersection locations.

In example embodiments, in order to promote effective horizontal movement of the plasma, the first passageways 126a of the pockets P of a same row of the jig 100a may be configured to align along a straight line in the second direction. Similarly, in some embodiments, the second passageways 126b of the pockets P of a same column of the jig 100a may be configured to align along a straight line in the first direction. In some embodiments, the first passageways 126a may be located along parallel straight lines and the second passageways 128a may be located along parallel straight lines. In some embodiments, the lines intersect the pockets P arranged in rows and columns on the jig 100a

In some embodiments, the pocket structures 120a may be provided in one of the first passageways 126a and the second passageways 128a. For example, the pocket structure 120a may include only the first passageways 126a formed at the first partition walls 122a in the second direction or only the second passageways 128a formed at the second partition walls 124a in the first direction, and not both. In some embodiments, the same can be true of the pocket structures 120 of the embodiment of FIGS. 1-3 described herein.

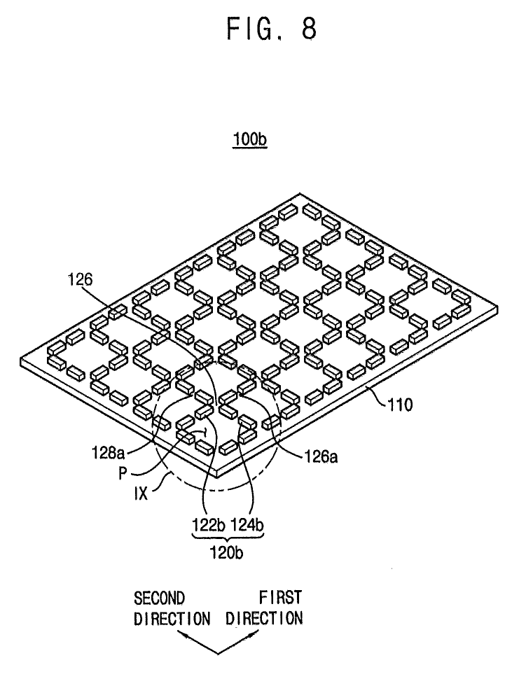

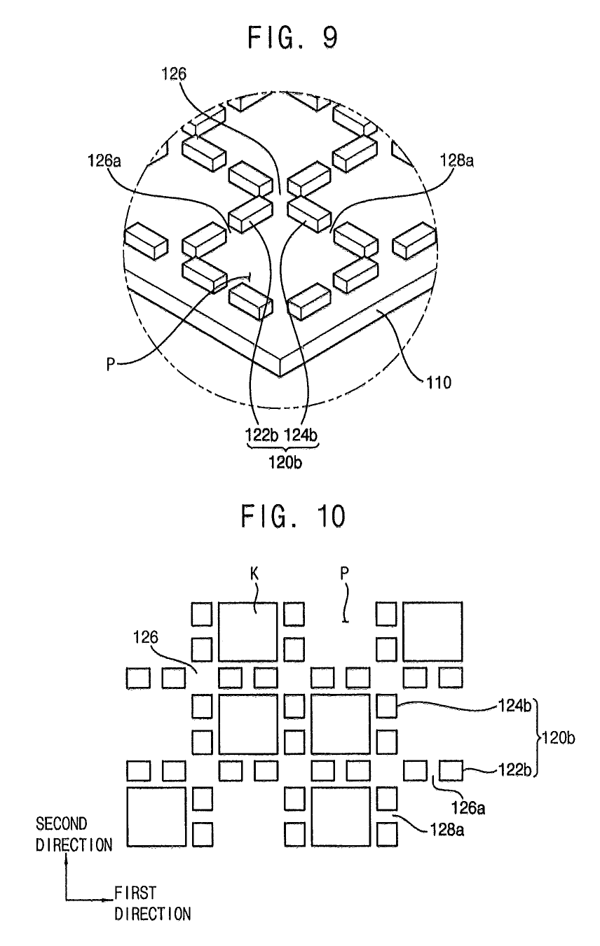

FIG. 8 is a perspective view illustrating a jig 100b in accordance with example embodiments in accordance with the inventive concepts, FIG. 9 is an enlarged perspective view of a portion IX of the embodiment of FIG. 8, and FIG. 10 is an enlarged plan view illustrating the jig of the embodiment of FIG. 8, in accordance with the inventive concepts.

A jig 100b of this example embodiment may include elements substantially the same as those of the jig 100 in FIG. 1 except for a pocket structure. Thus, the same reference numerals may refer to the same elements and any further illustrations with respect to the same elements may be omitted herein for brevity.

Referring to FIGS. 8 to 10, a pocket structure 120b of this example embodiment may include first partition walls 122b and second partition walls 124b. The first partition walls 122b and the second partition walls 124b may have arrangements substantially the same as those of the first partition walls 122 and the second partition walls 124 in FIG. 1.

In the present embodiment, in addition to the third passageways 126 positioned at the corner regions of the pockets P, as shown in the embodiment of FIGS. 1-3, first passageways 126a may be additionally formed in the first partition walls 122a, and second passageways 128a may be formed in the second partition walls 124a, as shown in the embodiment of FIGS. 5-7. In the present embodiment, the first passageways 126a are shown as being positioned at each of portions of the first partition walls 122a corresponding to each of central portions of the pockets P in the second direction, however, as described herein, herein the first passageways 126a can be located at positions other than the central portions. As described herein, the third passageways 126 may be formed at the points of intersection portions between the first partition walls 122b and the second partition walls 124b. That is, the third passageways 126 may correspond to the passageways 126 in FIG. 1.

Plasma Etching Apparatus

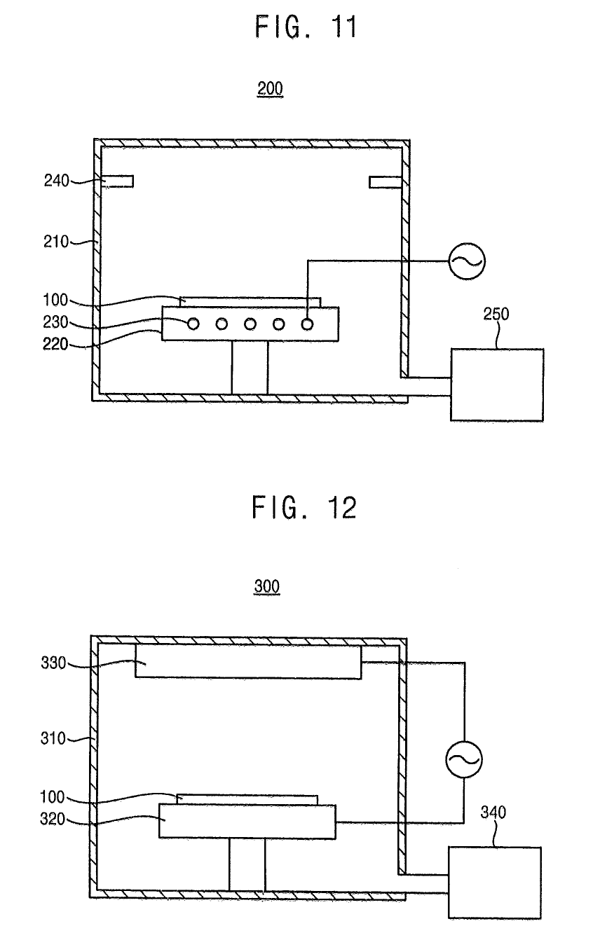

FIG. 11 is a cross-sectional view illustrating an inductively coupled plasma (ICP) etching apparatus including the jig 100 of the embodiments described herein in accordance with the inventive concepts.

Referring to FIG. 11, an ICP etching apparatus 200 of this example embodiment may include an etching chamber 210, a chuck 220, a jig 100, an antenna 230, a nozzle 240 and an exhaust pump 250.

The chuck 220 may be positioned on a bottom surface of the etching chamber 210. The antenna 230 may be positioned in the chuck 220. The nozzle 240 may be positioned at upper side walls of the etching chamber 210 to inject a reaction gas into the etching chamber 210. The antenna 230 may be electrically connected with an RF power source to generate the plasma from the reaction gas injected from the nozzle 240 over the chuck 220. The exhaust pump 250 may be connected to the bottom surface of the etching chamber 210 to exhaust byproducts.

The jig 100 may be placed on an upper surface of the chuck 220. The jig 100 may be configured to receive the semiconductor packages. The jig 100 may correspond to the jig in FIG. 1 so that any further illustrations with respect to the jig 100 may be omitted herein for brevity. Alternatively, the ICP etching apparatus 200 may include the jig 100a in FIG. 5 or the jig 100b in FIG. 8.

FIG. 12 is a cross-sectional view illustrating a capacitively coupled plasma (CCP) etching apparatus including the jig of the embodiment of FIG. 1 in accordance with the inventive concepts.

Referring to FIG. 12, a CCP etching apparatus 300 of this example embodiment may include an etching chamber 310, a chuck 320, a showerhead 330, a jig 100 and an exhaust pump 250.

The chuck 320 may be positioned on a bottom surface of the etching chamber 310. The showerhead 330 may be positioned at an upper surface of the etching chamber 310. The showerhead 330 may inject a reaction gas into the etching chamber 310. The chuck 320a and the showerhead 330 may be electrically connected with an RF power. Thus, the chuck 320 may function as a lower electrode. The showerhead 330 may function as an upper electrode. The exhaust pump 350 may be connected to the bottom surface of the etching chamber 310 to exhaust byproducts.

The jig 100 may be placed on an upper surface of the chuck 320. The jig 100 may be configured to receive the semiconductor packages. The jig 100 may correspond to the jig in FIG. 1 so that any further illustrations with respect to the jig 100 may be omitted herein for brevity. Alternatively, the CCP etching apparatus 300 may include the jig 100a in FIG. 5 or the jig 100b in FIG. 8.

According to example embodiments, the pocket structure may have the at least one passageway opening between the pockets. Accordingly, plasma may be caused to flow in a horizontal direction between neighboring pockets through the passageway. As a result, the passageways provide a pathway to promote the flow of plasma so the plasma may be uniformly distributed among the pockets and so that the native oxide layer present on the semiconductor packages positioned in the pockets may be effectively and uniformly removed using the plasma.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the inventive concepts. Accordingly, all such modifications are intended to be included within the scope of the present inventive concepts as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A jig comprising:
a base constructed and arranged to be exposed to plasma for etching a native oxide layer on electronic devices; and
a pocket structure on an upper surface of the base including pockets constructed and arranged to receive the electronic devices, the pocket structure having at least one passageway through which the plasma is moved in a horizontal direction between the pockets.

2. The jig of claim 1, wherein the pocket structure comprises:
first partition walls arranged on the upper surface of the base in a first direction; and
second partition walls arranged on the upper surface of the base in a second direction, the second direction being substantially perpendicular to the first direction.

3. The jig of claim 2, wherein the passageway is positioned at intersection locations of the first partition walls and the second partition walls.

4. The jig of claim 3, wherein a line passing through the passageways corresponds to a diagonal line of the pockets.

5. The jig of claim 2, wherein the passageway is positioned at the first partition walls.

6. The jig of claim 5, wherein a line passing through the passageways is substantially parallel to the second direction.

7. The jig of claim 5, wherein the passageway is positioned at a portion of the first partition walls corresponding to a central portion of the pockets.

8. The jig of claim 2, wherein the passageway is positioned at the second partition walls.

9. The jig of claim 8, wherein a line passing through the passageways is substantially parallel to the first direction.

10. The jig of claim 8, wherein the passageway is positioned at a portion of the second partition walls corresponding to a central portion of the pockets.

11. The jig of claim 2, wherein the passageway comprises:
first passageways positioned at the first partition walls; and
second passageways positioned at the second partition walls.

12. The jig of claim 11, wherein a line connected between the first passageways is substantially parallel to the second direction, and a line connected between the second passageways is substantially parallel to the first direction.

13. The jig of claim 1, wherein the base and the pocket structure comprise:
a metal plate; and
an insulating layer coated on the metal plate.

14. A plasma etching apparatus comprising:
an etching chamber;
a chuck on a bottom surface of the etching chamber;
a nozzle configured to inject a reaction gas into the etching chamber;
an antenna configured to generate plasma from the reaction gas over the chuck; and
a jig including a base and a pocket structure, the base arranged on an upper surface of the chuck and constructed and arranged to receive semiconductor packages, and the pocket structure arranged on an upper surface of the base, the pocket structure including pockets constructed and arranged to receive the semiconductor packages, the pocket structure having at least one passageway through which the plasma is moved in a horizontal direction between the pockets.

15. The plasma etching apparatus of claim 14, wherein the antenna is positioned in the chuck.

16. A jig in a plasma processing apparatus, comprising:
a base;
first partition walls on the base, the first partition walls extending in a first horizontal direction,
second partition walls on the base, the second partition walls extending in a second horizontal direction;
pocket structures comprising neighboring first partition walls and neighboring second partition walls, the pocket structures constructed and arranged to receive electronic devices for plasma processing;
passageways in at least one of the first partition walls or second partition walls.

17. The jig of claim 16 wherein the passageways are provided at corner regions of the pocket structures at intersection locations of the at least of the first partition walls or second partition walls.

18. The jig of claim 16 wherein the passageways are provided at side regions of the pocket structures in the at least one of the first partition walls or second partition walls.

19. The jig of claim 16 wherein the passageways are provided at corner regions of the pocket structures at intersection locations of the at least of the first partition walls and second partition walls, and at side regions of the pocket structures in the at least one of the first partition walls or second partition walls.

20. The jig of claim 16 wherein the first and second partition walls have a first height relative to the base and wherein the passageways have a second height relative to the base, the first height being greater than the second height.
